(19) United States
(12) Patent Application Publication
(10) Pub. No.: US 2026/0050047 A1
(43) Pub. Date: Feb. 19, 2026

(54) METHOD AND DEVICE FOR FAULT DETECTION AND METHOD AND SYSTEM FOR MONITORING AND/OR PERFORMING A PROTECTION FUNCTION, FOR A CURRENT TRANSFORMER

(71) Applicant: Siemens Aktiengesellschaft, München (DE)

(72) Inventors: Frank Mieske, Berlin (DE); Robert Matussek, Berlin (DE); Torsten Kerger, Schönwalde-Glien (DE)

(21) Appl. No.: 19/303,634

(22) Filed: Aug. 19, 2025

(30) Foreign Application Priority Data
Aug. 19, 2024 (EP) 24195166.4

(51) Int. Cl. G01R 31/62; H02H 7/04

(52) U.S. Cl. CPC G01R 31/62; H02H 7/042

(57) ABSTRACT

A method for detecting a fault, in particular an interruption, in a secondary circuit of a current transformer having a primary conductor formed by a part of a high-voltage conductor, includes inferring a fault in the secondary circuit if the magnitude of the mean current value relative to a time included within a selection time interval is less than a current value threshold. The selection time interval is determined based on a current value change variable and a current value change threshold. The current value change variable is formed based on at least two current values, assigned to different time points, of an electrical current flowing in the secondary circuit. A device for fault detection and a method and a system for monitoring and/or performing a protection function, for a current transformer, are also provided.

### CROSS-REFERENCE TO RELATED APPLICATION

This application claims the priority, under 35 U.S.C. § 119, of European Patent Application EP 24195166.4, filed Aug. 19, 2024; the prior application is herewith incorporated by reference in its entirety.

### FIELD AND BACKGROUND OF THE INVENTION

Irrespective of the grammatical gender of a specific term, persons with male, female or other gender identity are also included.

The invention relates to a method and a corresponding device for fault detection in a secondary circuit of a current transformer, the primary conductor of which is formed by a part of a high voltage conductor. Furthermore, the present invention relates to a method and a corresponding system for monitoring and/or performing a protective function of a high-voltage conductor.

### DESCRIPTION OF THE RELATED ART

In a high-voltage network or cable, current transformers can be conventionally provided for current measurement. The current transformers can forward measurement signals to downstream systems, which can perform protective functions for a protected object, such as a high-voltage line, based on the measured values of the current transformer. In the event of faults in the secondary circuit of the current transformers, however, false electrical states in the protection object can be simulated and protective functions can subsequently be performed incorrectly, which can lead, for example, to an interruption of a power supply for consumers.

It has been observed that fault detection for a current transformer cannot be performed satisfactorily or cannot be performed reliably under all conditions and circumstances by conventional methods.

### SUMMARY OF THE INVENTION

It is accordingly an object of the present invention to provide a method and a corresponding device for detecting a fault in the secondary circuit of a current transformer, in particular an interruption, wherein a fault can be reliably detected, in particular in order to avoid incorrectly performing or triggering protective functions. Furthermore, it is an object of the present invention to provide a method and a system for monitoring and/or implementing a protective function of the high-voltage conductor, which is also capable of detecting possible faults in a measuring device in order to thereby improve the monitoring, and also to implement a protective function only in the event of a reliably detected fault in the high-voltage conductor.

The object is achieved by the subject-matter of the independent claims, which are directed to a method and a device for detecting a fault in a secondary circuit of a current transformer. Furthermore, the object is achieved by the features of the method claim and system claim for monitoring and/or performing a protective function of a high-voltage conductor. The dependent claims specify particular embodiments of the present invention.

With the foregoing and other objects in view there is provided, in accordance with the invention, a method for detecting a fault, in particular an interruption, in a secondary circuit of a current transformer, the primary conductor of which is formed by a part of a high-voltage conductor, wherein the method comprises: inferring a fault in the secondary circuit if the magnitude of the mean current value relative to a time included within a selection time interval is less than a current value threshold, wherein the selection time interval is determined based on a current value change variable and a current value change threshold, wherein the current value change variable is formed based on at least two current values, assigned to different time points, of an electrical current flowing in the secondary circuit.

The method can be implemented in software and/or hardware. The method can be implemented, for example, as a part or module of a protective device, which is connected to the current transformer, for example, in order to receive measurement data of the current transformer. The current transformer is a measuring transducer which can generate an easily processable electrical signal, for example voltage signal, as a measure of a large electrical current that is difficult to measure. The current transformer can be configured as a transformer or include a transformer. The current transformer can deliver a secondary current in the secondary circuit as an output signal in the order of magnitude from milliamperes to several (e.g. 1 to 500) amperes, which can be proportional, for example, to the primary current to be measured in the high-voltage conductor. The secondary circuit can include a secondary coil with multiple windings. Depending on the high-voltage values in the high-voltage conductor, the current transformer can be adapted to the requirements.

The current transformer can be provided for protective purposes, in particular for transmitting a reduced current to one or more protective devices, such as protective relays, control units or control devices. The current transformer may be configured, for example, as an inductive current transformer, in which case it has only one or a few primary windings through which the primary current to be measured flows, as well as a larger number of secondary windings in the secondary circuit. The primary winding can be formed of a busbar, guided through a (ferromagnetic) toroidal core of the transformer, which corresponds to a single primary winding. The secondary current is reduced in relation to the primary current to be measured, and is inversely proportional to the ratio of the numbers of primary and secondary windings.

The secondary circuit can include a current meter. The current transformer can be connected on the secondary side via a cable, for example to a collection device and/or measuring device, and/or counter and/or protective device and/or control unit, for example to protect a protected object, for example the high-voltage line.

Conventionally, in the event of interruptions in the secondary circuit of the current transformer due to cable breakage, differential currents can be falsely simulated, for example in the case of differential protection, such as can also be caused by short circuits in the protected object. Conventionally this can lead to undesired overfunction of the differential protection and thus to incorrect tripping of a circuit breaker, thus endangering the stability of the power supply. Conventional methods for cable and wire break detection do not detect real cable breaks reliably (underfunction), while on the other hand the detection system responds incorrectly to small currents (overfunction).

Embodiments of the present invention provide a reliable detection of a fault in a secondary circuit of the current transformer, in particular an interruption. The method may include measuring a plurality of successive current values of a current flowing in the secondary circuit (which flows in the high-voltage conductor). The measurement can be repeated over time at a specified sampling frequency. The mean current value can be formed as a mean and/or RMS value and/or effective value of the current flowing in the secondary circuit. At least two current values, which are assigned to at least two different time points, are used to calculate the mean current value. For example, between 2 and 10 current values can be used to calculate the mean current value, with other numbers also being possible.

The current value threshold can be chosen such that it is below expected mean current values (for a fault-free high-voltage conductor). The magnitude of the mean current value can be compared with the current value threshold.

The selection time interval can be determined as a function of the current value change variable and the current value change threshold, and therefore can or does not have to include a fixed predetermined time period, but may be dependent on the electrical current characteristic of the current values determined in the secondary circuit. The current value change variable can represent a temporal change of at least two current values and can thus be determined, for example, at least from a difference of two current values which are assigned to different time points.

The current value change threshold can, but does not have to, have a fixed preset size. In particular, the current value change threshold can also be calculated dynamically as a function of the size of the secondary current.

If the selection time interval is determined based on or depending on the current value change variable and the current value change threshold, the reliability with which the fault is detected in the secondary circuit can be improved. In particular, the selection time interval can enable a delayed evaluation or test of whether the mean current value is below the current value threshold.

According to an embodiment of the present invention the selection time interval occurs from or after a first time at which a current jump has been detected, in particular at which at least one current value differs from an expected current value, in particular of a sinusoidal waveform, by more than a predetermined current value deviation.

If the current jump was also detected (in particular in advance), a reliability of the detection of the fault in the secondary circuit can be further improved. Expected current values can correspond, for example, to a sinusoidal or shifted sinusoidal curve. For example, differences between the observed current values and the expected current values can be formed and it can be determined, for example, whether the determined differences increase or decrease over time. For example, if the differences increase over time and are above a deviation threshold, a current jump can be inferred. Other algorithms for detecting a current jump can be used. For example, it is possible to compare the latest current measurement with that exactly one grid period before it, e.g. 20 ms at 50 Hz. If a deviation occurs, the AC current has changed in magnitude and/or phase.

According to one embodiment of the present invention, the selection time interval is not outside a limiting time interval of predetermined duration, which occurs after the first time point, and/or wherein the selection time interval has a duration of longer than 1 ms or longer than 1.5 ms.

The change in current or the waveform of the decay of the current to zero in the event of a wire break in the secondary circuit depends on the time constant of the secondary circuit, the ratio of its resistance to its inductance. The values of these electrical parameters vary in different applications and are generally unknown. The decay can last several milliseconds. Embodiments of the present invention may extend the time windows traditionally used for testing the current.

Through the use of an (absolute or fixed) limiting time interval, the evaluation or the test of whether the mean current value is below a current value threshold can be time-limited after the jump, in order not to incorrectly detect a fault in the secondary circuit of the current transformer. For example, the limiting time interval can have a duration of between 1 ms and 10 ms. For example, if the selection time interval has a duration of longer than 1 ms or even longer than 1.5 ms, faults in the secondary circuit of the current transformer that would conventionally go undetected can now be detected.

According to one embodiment of the present invention, the selection time interval includes at least one first time interval during which a magnitude of the current value change value is greater than the current value change threshold, wherein the first time interval extends in particular to a second time point.

The current value change variable can be greater than the current value change threshold before, during or after the detected current jump. During the first time interval, the change in the current is therefore greater than immediately before and immediately after it. The current value change threshold can be chosen in such a way that when the current is expected to be sinusoidal (i.e. in the absence of a fault in the high-voltage conductor), the current value change variable is always smaller than the current value change threshold. It can therefore be concluded that unusual changes in the current, which are not expected, occur or have occurred during the first time interval.

The first time interval can range from a time before, at, or after the first time point to the second time point, which can occur after the first time. If it is determined that at any time within the first time interval the mean current value is below the current value threshold, it can be inferred that there is a fault in the secondary circuit.

According to one embodiment of the present invention, the selection time interval includes at least one second time interval, which occurs after the first time interval and in particular has a predetermined duration, in particular between 0.5 ms and 2 ms, wherein in particular during the second time interval, the magnitude of the current value change variable is equal to or less than the current value change threshold.

If it is determined that the mean current value relative to a time within the second time interval is below the current value threshold, then a fault in the secondary circuit of the current transformer can also be inferred. The second time interval thus extends the criterion for inferring a fault in the secondary circuit. The duration of the second time interval can be determined, for example, from training data and can also be set according to the current value change threshold that is used. For example, the lower the current value change threshold chosen, the shorter the predetermined duration of the second time interval can be chosen. This allows the method to be adapted to the individual circumstances of the application.

According to one embodiment of the present invention, the method also allows the absence of a fault in the secondary circuit to be inferred if a current mean value relative to any time included in the selection time interval is greater than the current value threshold.

The selection time interval can include, for example, at least the first time interval or can include, for example, the first time interval and additionally the second time interval. If no fault was found to be present in the secondary circuit, the current values output by the current transformer can be assumed to have been caused by the currents in the high-voltage conductor.

According to one embodiment of the present invention, the current value change variable is determined proportional to a difference quotient of two current values or current mean values and two assigned time points, wherein in particular a proportional factor is determined based on a sampling frequency and a grid frequency.

This means the current value change variable can be calculated in a simple way from current values or mean current values. For example, the proportional factor can be a scaling factor or the proportional factor can be used for scaling. The scaling is described below using scale_D.

The current value change threshold and/or the current value threshold therefore do not need to be constant over time, but can change over time. This allows an appropriate scaling of the current value change threshold and/or the current value threshold to the actual electrical conditions, i.e. actual currents.

According to one embodiment of the present invention, the current value change threshold and/or the current value threshold is determined, in particular time-dynamically, based on at least one temporally assigned actual or nominal current value and/or mean current value and/or RMS current value or current value amplitude or effective current value, wherein the current value change threshold is defined to be greater than zero and in particular proportional to an RMS current value.

According to one embodiment of the present invention, the current value threshold is defined in particular proportional to a nominal effective current value, wherein a proportional factor is in particular between 3% and 10%, in particular 6%.

According to one embodiment of the present invention, the current values are obtained by repeated sampling, in particular with a sampling frequency of at least 1 kHz, and/or wherein the mean current value is calculated by averaging at least two, in particular between two and ten, current values.

The primary current may include, for example, a sinusoidal current, with a grid frequency of, for example, 50 Hz or 60 Hz. The sampling rate can be many times higher than the grid frequency. This allows an accurate determination of the current values.

According to one embodiment of the present invention, the current transformer is connected on the secondary side to a protective device, which is in particular configured to control at least one circuit breaker in the high-voltage conductor, and/or to implement at least one protective and/or monitoring function relating to the high-voltage conductor, in particular an undercurrent function. This allows the method to be used for monitoring and/or protective functions.

According to one embodiment of the present invention, the current values of the secondary circuit of the current transformer are used as measured values for determining a primary current that flows in the high-voltage conductor, wherein current values of the primary current are, for example, between 40 A and 50000 A, and/or wherein current values in the secondary circuit are, for example, between 0.5 A and 10 A. Other values are possible. This enables the use of the invention for monitoring and/or protective functions.

With the objects of the invention in view, there is also provided a method for monitoring and/or performing a protective function of a high-voltage conductor in which a primary current flows. The method comprises: using a current transformer, the primary conductor of which is formed by a part of the high-voltage conductor; detecting an undercurrent condition indicated by the current transformer; carrying out a method for detecting a fault, in particular an interruption, in a secondary circuit of the current transformer according to one of the preceding embodiments; if a fault is inferred in the secondary circuit: refraining from carrying out a protective function intended for a fault condition of the high-voltage conductor.

In the case of an undercurrent condition indicated by the current transformer, this makes it possible to differentiate between whether or not this fault condition has occurred due to a fault in the current transformer. If a fault in the secondary circuit of the current transformer is inferred, it is possible to avoid, for example, opening a circuit breaker in the high-voltage cable, which could prevent the continued operation of the supply grid.

According to one embodiment of the present invention, the method further includes, if no fault is found in the secondary circuit: carrying out a protective function intended for a fault condition of the high-voltage conductor.

In this case, it can be inferred that the current transformer is functioning correctly, so that the indicated undercurrent condition is caused by the condition of the high-voltage conductor. Therefore, if the protection function is performed, components of the supply grid can be protected from damage.

It should be understood that features which have been explained, provided, used or described individually or in any combination in connection with a method for detecting a fault in a secondary circuit of a current transformer, can be likewise applied, provided or used individually or in any combination to a device for detecting a fault in a secondary circuit of a current transformer, according to embodiments of the present invention, and vice versa.

With the objects of the invention in view, there is furthermore provided a device for detecting a fault, in particular an interruption, in a secondary circuit of a current transformer, the primary conductor of which is formed by a part of a high-voltage conductor, wherein the device comprises: a signal input, which is configured to receive current values of an electrical current flowing in the secondary circuit; a processor, which is configured to form a current value change variable based on at least two current values assigned to different time points; a logic module, which is configured to infer a fault in the secondary circuit if the magnitude of the mean current value relative to a time included within a selection time interval is less than a current value threshold, wherein the selection time interval is determined based on a current value change variable and a current value change threshold.

The device may be implemented with software and/or hardware, for example representing a part or a module of a protective device.

With the objects of the invention in view, there is concomitantly provided a system for monitoring and/or performing a protective function of a high-voltage conductor in which a primary current flows, wherein the system includes: a current transformer, the primary conductor of which is formed by a part of the high-voltage conductor; a device according to one of the preceding embodiments, the signal input of which is connected to the current transformer, a signal output for activating at least one protective function; wherein the system is configured, in the event of an undercurrent condition indicated by the current transformer, and in the event of a fault in the secondary circuit indicated by the logic module, to refrain from activating the protective function intended for a fault condition of the high-voltage conductor.

The system may further include, for example, a part of the high-voltage conductor and/or one or more further protective devices, which are connected, for example, to the current transformer and which are connected so as to control one or more circuit breakers in the high-voltage conductor. For example, the high-voltage conductor can form or represent one conductor of a multi-phase high-voltage cable of a power supply grid. The system may be configured to perform or control a method of monitoring and/or performing a protective function as mentioned above.

Embodiments of the present invention are now explained with reference to the appended drawings. The invention is not restricted to the illustrated or described embodiments.

Other features which are considered as characteristic for the invention are set forth in the appended claims.

Although the invention is illustrated and described herein as embodied in a method and a device for fault detection and a method and a system for monitoring and/or performing a protection function, for a current transformer, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 is a schematic block diagram of a system for monitoring and/or performing a protective function of a high-voltage conductor according to an embodiment of the present invention, including a device for detecting a fault in a current transformer according to an embodiment of the present invention;

FIG. 2 is a diagram illustrating current variables calculated according to embodiments of the present invention; and

FIG. 3 is a diagram illustrating current variables analyzed in accordance with embodiments of the present invention for detecting a fault in a current transformer.

### DETAILED DESCRIPTION OF THE INVENTION

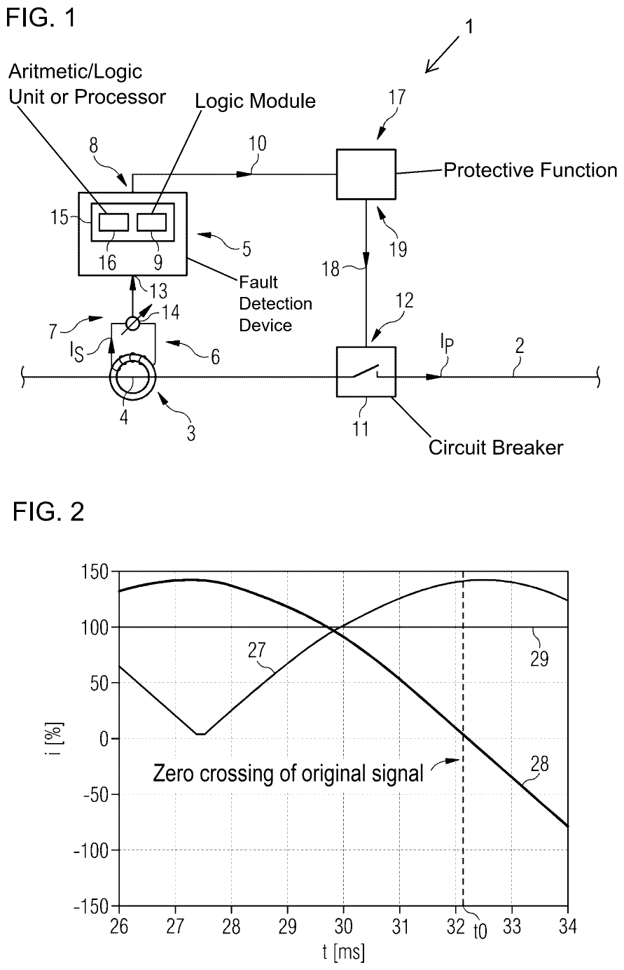

Referring now to the figures of the drawings in detail and first, particularly, to FIG. 1 thereof, there is seen a schematically-illustrated system 1 for monitoring and/or performing a protective function of a high-voltage conductor 2 in which a primary current I_P flows, including a current transformer 3, the primary conductor 4 of which is formed by a part of the high-voltage conductor 2.

The system 1 further includes a device 5 for detecting a fault in a secondary circuit 6 of the current transformer 3, wherein a signal input 7 of the device 5 is connected to the current transformer, in particular to its secondary circuit 6. The system, in particular the device 5, additionally has a signal output 8, for activating a circuit breaker. The system is configured to refrain from activating a protective function 17, as is provided for an undercurrent condition of the high-voltage conductor 3, in the event of an undercurrent condition indicated by the current transformer 2 and in the event of a fault in the secondary circuit indicated by a logic module 9.

In the illustrated embodiment, the system 1 further includes a circuit breaker 11, which is provided and disposed for the controlled interruption of the high-voltage conductor 2. The circuit breaker can be controlled via a control input 12. In the illustrated embodiment, the circuit breaker 11 is controlled by a control signal 18, which is output at the control output 19 of the protective function 17. If the current transformer 3 is working correctly, the circuit breaker 11 can be opened by the control signal 18 when a fault condition is indicated, in order to interrupt a current, for example.

In other embodiments, one or more other protective devices or actuators can be controlled by a control signal 18 (and/or by control signal 10), for example, in order to perform one or more protective functions individually upon a fault being detected in the high-voltage conductor 2.

The device 5 for detecting a fault in the secondary circuit 6 of the current transformer 3 includes the signal input 7, which is configured to obtain current values 13 of an electrical current I_S flowing in the secondary circuit 6 of the current transformer 3. In the illustrated embodiment, a current meter 14 is disposed in the secondary circuit 6 to measure the current I_S and output the corresponding measured values as measurement signals 13 and supply them to the device 5.

In the illustrated embodiment, the device includes an arithmetic/logic unit 15, which is configured to perform arithmetic and/or logical functions. In particular, the unit 15 includes a processor 16, which is configured to form a current value change variable based on at least two current values (e.g. represented by measured values 13), assigned to different time points. The device 5 further includes the logic module 9, which is configured to infer a fault in the secondary circuit 6 of the current transformer 3 if a mean current value relative to a time included within a selection time interval is less than a current value threshold. The selection time interval is determined based on a current value change variable and a current value change threshold as described in detail below.

For example, by using the current meter 14, the current signal I_S in the secondary circuit 6 of the current transformer can be sampled at a sampling frequency of, for example, 8 kHz (other values are possible). Embodiments of the present invention can infer a wire break in the secondary circuit 6 of the current transformer 3 if the amplitude of the current samples within a selection time interval after a current jump falls monotonically below a threshold value, for example below 6% of the nominal current. For example, the mean value I_MEAN of the amplitudes of the current values can be determined using four sampling values according to the following formula:

$${I}_{MEAN} ( n ) = 0.25 {\sum }_{k = 1}^{4} i ( n - 4 + k ) \qquad ( 1 )$$

where n denotes the sampling time point in the signal and i denotes the amplitude of a sampled value. According to embodiments of the present invention a mean current value can be determined in other ways, for example, by averaging over more or fewer samples or, for example, it can also be determined as an RMS value averaged over one or two or more sampled values.

According to one embodiment of the present invention, a wire break in the secondary circuit 6 of the current transformer 3 is detected by analyzing a current value change variable in conjunction with a mean current value. A wire break in the secondary circuit is characterized by a higher gradient of the decreasing current in comparison to the gradient of a sinusoidal current waveform.

FIG. 2 illustrates, in a coordinate system in which the abscissa indicates the time and the ordinate the proportion of a nominal amplitude, current value curves of a sinusoidal current with no faults in the secondary circuit, which are analyzed according to embodiments of the present invention. Curve 27 illustrates the magnitude of the difference quotient of a sinusoidal current (curve 28) with an effective value of 100%. At a zero crossing of the current values (curve 28), i.e. at a time to, the difference quotient (curve 27) has the maximum of √2 of the effective value of the sinusoidal signal. The region around the zero crossing of the expected signal for a normal expected sine wave (curve 18) has significantly lower gradients than when a sharp drop in the current values occurs, as in the event of a wire break. Curve 29 represents the RMS value of the current values, which for an expected sinusoidal waveform at nominal amplitude is constant at 100%.

From FIG. 2 it is evident that the highest gradient (curve 27) of an expected regular sinusoidal current (curve 28) occurs in the zero crossing of the current. The value of this gradient thus determines the minimum current value change threshold for discriminating a wire break.

According to one embodiment of the present invention, the first derivative or the difference quotient is used as a suitable criterion for detecting a wire break. According to one embodiment of the present invention, the current value change variable (e.g. difference quotient (I_MEAN_D)) can be calculated according to the following formula:

$${I}_{MEAN \_ D} ( n ) = \frac{Δ {I}_{MEAN}}{Δ {T}_{A}}$$

By selecting a sampling time interval of 0.5 ms, corresponding to a sampling frequency of 2 kHz, the following relationship is obtained with respect to the 8 kHz data stream:

$${I}_{MEAN \_ D} ( n ) = \frac{Δ {I}_{MEAN}}{Δ {T}_{A}} = ( {I}_{MEAN} ( n ) - {I}_{MEAN} ( n - 4 ) ) {scale}_{d} \qquad ( 2 )$$

where n denotes the sampling time point in the signal. As can be obtained from the above formula (2), the current value change variable can be determined as being proportional to a difference quotient of two current values or mean current values of two assigned time points.

The scale factor scale_D of the difference quotient to the sinusoidal signal amplitude of the grid frequency f can be realized, for example, with the following factor:

$${scale}_{d} = \frac{1}{\sqrt{2 + 2 cos \frac{2 π f}{{f}_{A}}}}$$

where f_A is the sampling frequency of the difference quotient formation (in the example 2 kHz) and f is the current signal frequency (grid frequency).

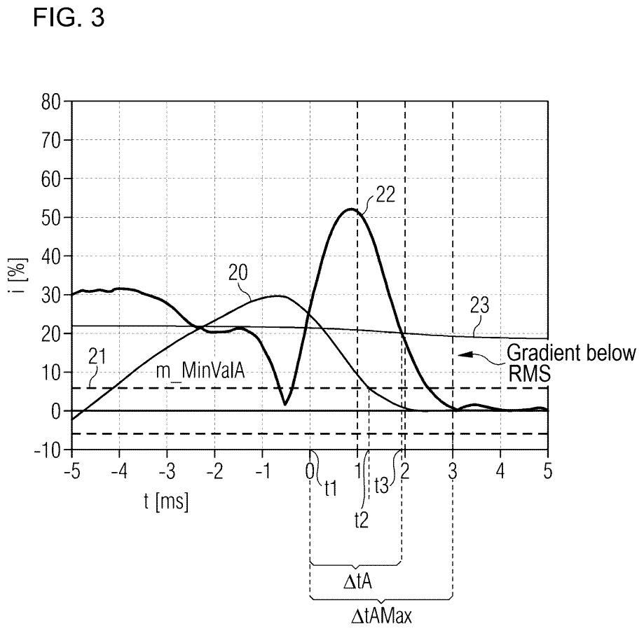

FIG. 3 shows curves in a coordinate system in which the abscissa indicates the time and the ordinate indicates the proportion of amplitude. Curve 20 illustrates the variation of the mean current value. Curve 21 illustrates the variation of a current value threshold, curve 22 illustrates the variation of a magnitude of a current value change variable (here as calculated in equation (2) above), and curve 23 illustrates the variation of a current value change threshold, as provided according to embodiments of the present invention.

At a first time t1, a current jump is detected, for example if at least one current value differs from an expected current value by more than a predetermined current value deviation. According to one embodiment of the present invention, a current value change variable (e.g. curve 22) is also determined starting from this first time t1 in order to compare it with the current value change threshold (curve 23). According to one embodiment of the present invention, within a selection time interval ΔtA it is determined whether there is an instant within this selection time interval ΔtA in which the magnitude of the mean current value 20 is lower than the current value threshold 21. In the present example, from time t2 within the selection time interval ΔtA, the current mean value 20 is lower than the current value threshold 21 and a fault is inferred in the secondary circuit 6 of the current transformer 3.

The selection time interval ΔtA includes the time interval during which a magnitude 22 of the current value change variable is greater than the current value change threshold 23.

Thus, the selection time interval ΔtA extends exactly as far as a third time t3, at which the magnitude 22 of the current value change variable crosses the current value change threshold 23 from above to below.

According to another embodiment, the maximum length of the selection time interval ΔtA may have a predetermined duration ΔtAMax. If the mean current value 20 is (always) greater than the current value threshold 21 within the entire evaluation time interval ΔtAMax, it can be concluded that there is no fault present in the secondary circuit 6 of the current transformer. For example, the interval ΔtAMax can extend to a time that is, for example, 1 ms or longer than 1 ms after the third time t3. For example, the interval ΔtAMax can start at the first time t1 and have a duration of between 1 ms and 3 ms.

As can be seen from FIG. 3, both the current value change threshold 23 and the current value threshold 21 can be determined dynamically as a function of time based on an actual or nominal current value and/or mean current value or RMS current value or current value amplitude or effective current value. In particular, the current value change threshold 23 is not constant over time, but varies with time.

As can be seen from FIG. 1, the current transformer 3 is connected on the secondary side to the device 5, which can also be configured as a protective device and for this purpose has the control input 7 and the control output 8, as described in more detail above.

The current values 13 of the secondary circuit 6 are used to determine the primary current I_P that flows in the high-voltage conductor 3.

The device 5 and/or the system 1, which are illustrated in FIG. 1, can be configured to carry out a method for detecting a fault in the secondary circuit 6 of the current transformer 3 and/or to carry out or control a method for monitoring or carrying out a protective function of a high-voltage conductor.

FIG. 3 illustrates the absolute signal waveform 22 of the difference quotient I_MEAN_D for the real wire break in the secondary circuit of the current transformer. The magnitude of the difference quotient (curve 22) one millisecond after the jump (at the first time t1) is higher than the current value change threshold 23, i.e. in the case illustrated here, greater than the threshold value F_D×I_RMS, although the mean value (curve 20) after one millisecond is not below the minimum current threshold (curve 21). Two milliseconds after the jump, the difference quotient (curve 22) is lower than the threshold value (curve 23) and the minimum criterion is met. This means that a wire break can be reliably detected by a delayed analysis according to an embodiment of the present invention.

The maximum difference quotient of a sinusoidal signal occurs at the zero crossing and is exactly equal to √2 of the RMS value. The factor F_D can be chosen such that a distinction can be made between wire break and sinusoidal current waveform, wherein higher gradients occur in the event of a wire break. If the factor is chosen to be greater than √2, for example 2, an incorrect wire break detection for a sinusoidal signal can be avoided. At the same time, however, a valid wire break can also be detected in the event of a wire break near the zero crossing, as the test for the minimum current criterion is only delayed and no immediate rejection is made.

The difference quotient criterion can be applied in the case of a suspected wire break, that is, after a current jump has been detected (state “falling”), in such a way that the “falling” state is maintained for as long as the magnitudes of the difference quotient exceed a threshold value. Thus, the RMS value of the sampled signal is multiplied by a factor F_D, for example, 2. In addition, a maximum number of measurement repetitions m can be defined for which the criteria of difference quotient and minimum are tested.

TABLE 1

| I_{MEAN D} > F_{D} TrueRMS | I_{MEAN D} ≤ F_{D} TrueRMS | |
|---|---|---|
| Maintaining the “FALLING” | /_{MEAN} < minVal | /_{MEAN} > minVal |
| state, after m measurement | è “WIRE BREAK” | è “REJECTION” |
| repetitions −> “REJECTION” | | |

If the difference quotients fall below the threshold value F_D×I_RMS, it is checked immediately to see whether the mean value I_MEAN of the samples falls below the Minimum threshold value. In this case, a valid wire break must be assumed, otherwise, no wire break is assumed (see Table 1).

According to embodiments of the present invention, the additional criterion of the difference quotients enables a reliable wire break detection in a secondary circuit of a current transformer. In addition, the erroneous detection of a wire break is avoided. The introduction of the additional criterion thus leads to a significant improvement in wire break detection. This allows a better ability to distinguish between normal processes in the grid and faults in the secondary circuit of the current transformer. In particular, the trip reliability and stability of differential protective functions can thus be improved.

1. A method for detecting a fault or an interruption in a secondary circuit of a current transformer having a primary conductor formed by a part of a high-voltage conductor, the method comprising:
inferring a fault in the secondary circuit upon a magnitude of a mean current value relative to a time included within a selection time interval being less than a current value threshold;
determining the selection time interval based on a current value change variable and a current value change threshold; and
forming the current value change variable based on at least two current values, assigned to different time points, of an electrical current flowing in the secondary circuit.

2. The method according to claim 1, which further comprises at least one of including a first time at which a current jump has been detected in the selection time interval, or causing the selection time interval to occur after the first time at which a current jump has been detected.

3. The method according to claim 2, which further comprises defining the current jump as at least one current value differing from an expected current value or a current value of a sinusoidal waveform, by more than a predetermined current value deviation.

4. The method according to claim 2, which further comprises providing the selection time interval at least one of:
not outside of a maximum limiting time interval of predetermined duration, occurring after the first time, or
with a duration of at least 1 ms.

5. The method according to claim 2, which further comprises providing the selection time interval with a time interval during which a magnitude of the current value change variable is greater than the current value change threshold.

6. The method according to claim 5, which further comprises extending the selection time interval to a third time.

7. The method according to claim 1, which further comprises inferring an absence of a fault in the secondary circuit upon the mean current value relative to any time included in the selection time interval being greater than the current value threshold.

8. The method according to claim 1, which further comprises determining the current value change variable proportional to a difference quotient of two current values or mean current values and two assigned time points.

9. The method according to claim 8, which further comprises determining a proportional factor based on a sampling frequency and a current frequency.

10. The method according to claim 1, which further comprises:
determining at least one of the current value change threshold or the current value threshold based on at least one of at least one temporally assigned actual or nominal current value or the mean current value or RMS current value or current value amplitude or effective current value; and
selecting the current value change threshold to be greater than zero.

11. The method according to claim 10, which further comprises carrying out the determination of at least one of the current value change threshold or the current value threshold time-dynamically, and selecting the current value change threshold to be defined proportional to an RMS current value, with a proportional factor greater than √2.

12. The method according to claim 1, which further comprises defining the current value threshold proportional to a nominal effective current value, with a proportional factor of between 3% and 10%.

13. The method according to claim 1, which further comprises at least one of:
obtaining the current values by repeated sampling, or
calculating the mean current value by averaging at least two current values.

14. The method according to claim 13, which further comprises carrying out obtaining the current values by repeated sampling with a sampling frequency of at least 1 kHz, and calculating the mean current value by averaging between two and ten current values.

15. The method according to claim 1, which further comprises:
connecting the current transformer on a secondary side to a protective device configured to at least one of:
control at least one circuit breaker in the high-voltage conductor, or
implement at least one of at least one protective or monitoring function relating to the high-voltage conductor.

16. The method according to claim 1, which further comprises using the current values of the secondary circuit of the current transformer as measured values for determining a primary current flowing in the high-voltage conductor.

17. A method for at least one of monitoring or performing a protective function of a high-voltage conductor in which a primary current flows, the method comprising:
providing a current transformer having a primary conductor formed by a part of the high-voltage conductor;
detecting an undercurrent condition indicated by the current transformer;
carrying out the method for detecting a fault or an interruption in the secondary circuit of the current transformer according to claim 1; and
upon identifying a fault in the secondary circuit:
refraining from carrying out a protective function intended for a fault condition of the high-voltage conductor.

18. The method according to claim 17, which further comprises:
when no fault is identified in the secondary circuit:
carrying out a protective function intended for a fault condition of the high-voltage conductor.

19. A device for detecting a fault or an interruption in a secondary circuit of a current transformer having a primary conductor formed by a part of a high-voltage conductor, the device comprising:
a signal input configured to receive current values of an electrical current flowing in the secondary circuit;
a processor configured to form a current value change variable based on at least two current values assigned to different time points; and
a logic module configured to infer a fault in the secondary circuit upon a magnitude of a mean current value relative to a time included within a selection time interval being less than a current value threshold;
the selection time interval being determined based on a current value change variable and a current value change threshold.

20. A system for at least one of monitoring or performing a protective function of a high-voltage conductor in which a primary current flows, the system comprising:
a current transformer having a primary conductor formed by a part of the high-voltage conductor;
the device according to claim 19, the signal input of the device being connected to the current transformer; and
a signal output for activating at least one protective function;
the system being configured to refrain from activating the protective function intended for a fault condition of the high-voltage conductor:
in an event of an undercurrent condition indicated by the current transformer, and
in an event of a fault in the secondary circuit indicated by the logic module.
